(19) United States
(12) Patent Application Publication
(10) Pub. No.: US 2009/0091810 A1
(43) Pub. Date: Apr. 9, 2009

(54) HOLOGRAM RECORDING MATERIAL AND HOLOGRAM RECORDING MEDIUM

(75) Inventors: Jiro Yoshinari, Tokyo (JP); Atsuko Kosuda, Tokyo (JP); Naoki Hayashida, Tokyo (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TDK CORPORATION, Tokyo (JP)

(21) Appl. No.: 12/236,123

(22) Filed: Sep. 23, 2008

(30) Foreign Application Priority Data
Oct. 5, 2007 (JP) 2007-262754

(51) Int. Cl. G03H 1/02; G03F 7/004

(52) U.S. Cl. 359/3; 430/2

(57) ABSTRACT

The present invention provides a hologram recording material and a hologram recording medium, suitable for volume hologram recording, that are excellent in multiple recording characteristics and stability over time in holographic memory recording using a blue laser as well as a green laser. A hologram recording material comprising at least metal compound fine particles and a photopolymerizable compound, wherein the metal compound fine particles comprise organometallic fine particles which contain a metal atom, an organic group, and an oxygen atom, have a direct bond between the metal atom and a carbon atom in the organic group (a metal-carbon bond), and have a bond between the metal atoms through the oxygen atom (a metal-oxygen-metal bond); and the metal compound fine particles are not crosslinked with each other. A hologram recording medium (11) having the hologram recording material layer (21).

### BACKGROUND OF THE INVENTION

1. Field of the Invention

The present invention relates to a hologram recording material suitable for volume hologram recording, and a hologram recording medium having a hologram recording layer comprising the hologram recording material. The present invention relates in particular to a hologram recording material suitable for record and reproduction using not only a green laser light but also a blue laser light, and a hologram recording medium having a hologram recording layer comprising the hologram recording material.

2. Disclosure of the Related Art

Hitherto, magnetic recording media and optical recording media have widely been used as information-recording media. A magnetic recording medium and an optical recording medium are each a medium wherein information is two-dimensionally recorded/reproduced. In order to make the recording density high, it is necessary to make information bits fine.

Research and development of holographic memories have been advanced as large-capacity recording technique making high-speed transmission possible. Characteristics required for a hologram recording material are high refractive index change, high sensitivity, low scattering, environment resistance, durability, low dimensional change, high multiplicity and so on, in recording. So far, about holographic memory recording using a green laser, various reports have been made.

As a holographic memory recording material, known is a material made basically of a photopolymerization reactive compound and a binder.

Known is a photopolymer material made mainly of an organic binder polymer and a photopolymerizable monomer. However, the photopolymer material has problems about its dynamic range property, environment resistance, durability, and so on. In order to solve the problems of the photopolymer material, the use of a binder other than organic binder polymers has been investigated.

For example, Japanese Patent No. 2953200 discloses a film for optical recording wherein a photopolymerizable monomer or oligomer, and a photopolymerization initiator are contained in an inorganic substance network film. However, the compatibility between the inorganic substance network and the photopolymerizable monomer or oligomer is bad. Therefore, a uniform film is not easily obtained. In particular, in the case of setting the film thickness to 100 μm or more, which is required to attain a high multiplicity, a uniform film is not easily formed. The nonuniformity of the film causes a problem of light scattering. In a case where the film thickness is 100 μm or more, light scattering becomes a very serious problem. Namely, the light transmittance of the hologram recording material is lowered by light scattering, or noises are generated in recorded data by scattered light. According to the publication, scattering and other recording characteristics in a case where the film thickness is 100 μm or more are not investigated. A specific disclosure of the publication is that a photosensitive layer having a thickness of about 10 μm (par. [0058]) is exposed to an argon laser having a wavelength of 514.5 nm (par. [0059]).

JP-A-11-344917 discloses an optical recording medium comprising a photoactive monomer in an organic-inorganic hybrid matrix. The organic-inorganic hybrid matrix contains a three-dimensional inorganic scaffolding (Si—O—Si—O) to which an organic moiety (alkyl group and/or aryl group) is attached (par. [0007]). However, according to the present inventors' investigation, the compatibility between such a three-dimensional inorganic matrix to which an organic moiety is attached and a photoactive monomer is not good. Therefore, a uniform film is not easily obtained. The nonuniformity of the film causes a problem of light scattering. Additionally, the migration of the photoactive monomer is hindered by the matrix structure, so that the monomer is not effectively photopolymerized. A specific disclosure of the publication is that record was made in a hologram recording layer having a thickness of 100 μm, using a YAG laser having a wavelength of 532 nm (Example 3, par. [0031]).

JP-A-2002-236439 discloses a hologram recording material comprising: a matrix made of an organic-inorganic hybrid polymer obtained by copolymerizing an organometallic compound containing an ethylenically unsaturated double bond and an organic monomer having an ethylenically unsaturated double bond, as main chain constituting components, and/or a hydrolyzed polycondensate thereof; a photopolymerizable compound; and a photopolymerization initiator. By the introduction of the large organic main chain component into the matrix material, the compatibility between the matrix and the photopolymerizable compound is improved. However, the introduction of the large organic main chain component permits the presence of a two-component structure of the organic main chain and an inorganic network in the matrix material. Thus, it appears that the matrix may not exhibit unified behavior at the time of recording so as to cause nonuniform recording. If the ratio of the organic main chain component in the matrix is large, the same problems as in the case of the above-mentioned photopolymer material, which uses an organic binder polymer, are caused. A specific disclosure of the publication is that a hologram recording material layer having a thickness of 20 μm (par. [0080]) is exposed to an argon laser having a wavelength of 514.5 nm (par. [0081]).

As described above, at present, there has not been developed any three-dimensional crosslinked matrix that is suitable for a hologram recording material wherein a binder other than organic binder polymers is used.

In the meantime, an investigation is also made about the use of a binder other than organic binder polymers that does not have any three-dimensional crosslinked matrix structure.

For example, JP-A-2003-84651 discloses a hologram recording material comprising a compound having one or more polymerizable functional groups (functional compound), a photopolymerization initiator, and inorganic fine particles. The publication exemplifies, as the inorganic fine particles, a metal oxide, a metal nitride, a metal carbide, a semiconductor, or a simple substance of metal, and discloses that in order to disperse the particles evenly, it is preferred to chemically modify the surface of the fine particles at the time of producing the particles, or add a dispersant to the fine particles after producing the particles (pars. [0032] to [0033]).

The publication discloses, in paragraph [0030], that a particle diameter of the inorganic fine particles is set to 400 nm or less, and preferably set to 200 nm or less. Specifically, in Example 1, silica fine particles having an average particle diameter (median) of 97.1 nm were used; and in Example 2, titania fine particles having an average particle diameter (median) of 66.8 nm were used. According to the present inventors' investigations, when hologram recording using a blue laser is supposed, such a large particle diameter causes Rayleigh scattering so that good recording characteristics are not easily obtained.

The publication discloses, in paragraph [0030], that the ratio by volume of the inorganic fine particles to the whole of the inorganic fine particles and the resin component, in the state that the functional compound is polymerized, is preferably 3% by volume or more. Specifically, in Example 1, the ratio by volume was 37.3% by volume (50% by weight); and in Example 2, the ratio by volume was 38.4% by volume (68% by weight). From the present inventors' investigations, it is considered that for such an amount of the inorganic fine particles, the amount of the functional compound is too large so that large polymerization shrinkage is caused when the recording material is exposed to light for recording or exposed to light for post-curing so as to cause the functional compound to react for photopolymerization. Alternatively, it is indispensable to select or develop a functional compound wherein polymerization shrinkage is not to be generated.

JP-A-2005-77740 discloses a hologram recording material comprising metal oxide particles, a polymerizable monomer and a photopolymerization initiator wherein the metal oxide particles are treated with a surface treating agent in which a hydrophobic group and a functional group which can undergo dehydration-condensation with a hydroxyl group on the surface of the metal oxide particles are bonded to a metal atom; and the metal atom is selected from the group consisting of titanium, aluminum, zirconium, and chromium.

JP-A-2005-99612 discloses a hologram recording material comprising a compound having one or more polymerizable functional groups, a photopolymerization initiator, and colloidal silica particles.

JP-A-2005-321674 discloses a hologram recording material comprising: an organometallic compound at least containing at least two kinds of metals (Si and Ti), oxygen, and an aromatic group, and having an organometallic unit wherein two aromatic groups are directly bonded to one metal (Si); and a photopolymerizable compound.

JP-A-2007-156452 discloses a hologram recording material comprising: an organometallic compound at least containing at least two kinds of metals (Si and Ti), oxygen, and an aromatic group, and having an organometallic unit wherein two aromatic groups are directly bonded to one metal (Si); metal oxide fine particles; and a photopolymerizable compound.

Japanese Patent Application National Publication No. 2005-514645 discloses a process for producing a hologram recording material having nano-scale particles embedded in a solid matrix. The solid matrix is produced from a thermally or photochemically curable matrix material. In Examples, a hydrolyzable and condensable silane-polyvinyl butyral (PVB) mixture was used.

### SUMMARY OF THE INVENTION

An object of the present invention is to provide a hologram recording material suitable for volume hologram recording that is excellent in multiple recording characteristics and stability over time in holographic memory recording using a blue laser as well as a green laser. Another object of the present invention is to provide a hologram recording medium having a hologram recording layer comprising the hologram recording material.

The present inventors have made the present invention by use of metal compound fine particles having no three-dimensional crosslinkages therebetween, and a photopolymerizable monomer.

The present invention includes the followings:

(1) A hologram recording material comprising at least metal compound fine particles and a photopolymerizable compound,

wherein the metal compound fine particles comprise organometallic fine particles which contain a metal atom, an organic group, and an oxygen atom, have a direct bond between the metal atom and a carbon atom in the organic group (a metal-carbon bond), and have a bond between the metal atoms through the oxygen atom (a metal-oxygen-metal bond); and

the metal compound fine particles are not crosslinked with each other.

(2) The hologram recording material according to the above-described (1), wherein a particle diameter of the metal compound fine particles is 0.5 nm or more and 50 nm or less, the particle diameter being represented by a mode value of a particle size distribution of said fine particles as determined by a dynamic light scattering method.
(3) The hologram recording material according to the above-described (1) or (2), wherein the organometallic fine particles contain at least two kinds of metals as the metal atom, one of the at least two kinds of metals is Si, and the metal(s) other than Si is/are selected from the group consisting of Ti, Zr and Ta.
(4) The hologram recording material according to the above-described (3), wherein a complexing ligand is coordinated to at least one portion of said metal atom other than Si in the organometallic fine particles.

In the present specification, a complexing ligand is a ligand which is capable of forming a complex with a metal atom by coordination.

(5) The hologram recording material according to any one of the above-described (1) to (4), wherein the metal compound fine particles further comprise metal complex fine particles which contain a metal atom and an oxygen atom, have a bond between the metal atoms through the oxygen atom (a metal-oxygen-metal bond), and have a complexing ligand coordinated to at least one portion of said metal atom; and

the metal compound fine particles are not crosslinked with each other.

(6) The hologram recording material according to any one of the above-described (1) to (5), wherein the metal compound fine particles are contained in an amount of 70% by weight or more and 95% by weight or less with respect to the hologram recording material as a nonvolatile component.
(7) The hologram recording material according to any one of the above-described (1) to (6), which further comprises a photopolymerization initiator.
(8) A hologram recording material comprising at least metal compound fine particles and a photopolymerizable compound,

wherein the metal compound fine particles comprise metal complex fine particles which contain a metal atom and an oxygen atom, have a bond between the metal atoms through the oxygen atom (a metal-oxygen-metal bond), and have a complexing ligand coordinated to at least one portion of said metal atom; and

the metal compound fine particles are not crosslinked with each other.

(9) The hologram recording material according to the above-described (8), wherein a particle diameter of the metal compound fine particles is 0.5 nm or more and 50 nm or less, the particle diameter being represented by a mode value of a particle size distribution of said fine particles as determined by a dynamic light scattering method.
(10) The hologram recording material according to the above-described (8) or (9), wherein the metal compound fine particles are contained in an amount of 70% by weight or more and 95% by weight or less with respect to the hologram recording material as a nonvolatile component.
(11) The hologram recording material according to any one of the above-described (8) to (10), which further comprises a photopolymerization initiator.
(12) A hologram recording medium having a hologram recording layer comprising the hologram recording material according to any one of the above-described (1) to (11).
(13) The hologram recording medium according to the above-described (12), wherein recording and reproducing are attained using a laser light having a wavelength of 350 to 450 nm.
(14) The hologram recording medium according to the above-described (12) or (13), wherein the hologram recording layer has a thickness of at least 100 μm.
(15) A holographic memory system, using a hologram recording medium having a hologram recording layer comprising the hologram recording material according to any one of the above-described (1) to (11).

The hologram recording material of the present invention comprises specified metal compound fine particles having no three-dimensional crosslinkages between the fine particles, and a photopolymerizable monomer. Since the metal compound fine particles are particles that are not three-dimensionally crosslinked with each other, the photopolymerizable monomer is not hindered from migrating in the recording material. Moreover, since the organometallic fine particles as the metal compound fine particles have an organic group, the organometallic fine particles are good in compatibility with the photopolymerizable monomer; and the dispersibility of the particles and the monomer is also good in the recording material. Since the metal complex fine particles as the metal compound fine particles have an organic group in the ligand moiety, the metal complex fine particles are good in compatibility with the photopolymerizable monomer; and the dispersibility of the particles and the monomer is also good in the recording material. Thus, according to the present invention, provided is a hologram recording material suitable for volume hologram recording that is excellent in multiple recording characteristics and stability over time.

### BRIEF DESCRIPTION OF THE DRAWINGS

FIG. 1 is a view illustrating a schematic cross section of a hologram recording medium produced in the example.

FIG. 2 is a plane view illustrating the outline of a hologram recording optical system used in the example.

### DETAILED DESCRIPTION OF THE INVENTION

A hologram recording material of the present invention is a composition comprising, as essential components, organometallic fine particles and/or metal complex fine particles as the metal compound fine particles, and a photopolymerizable compound (photopolymerizable monomer). A hologram recording medium of the present invention has a hologram recording layer comprising the hologram recording material. In the present specification, the hologram recording layer may be referred to as a hologram recording material layer.

The organometallic fine particles are particles made of an organometallic compound, and are particles which contain a metal atom, an organic group, and an oxygen atom and which have a direct bond between the metal atom and a carbon atom in the organic group (metal-carbon bond), and a bond between the metal atoms through the oxygen atom (metal-oxygen-metal). The organometallic fine particles are not crosslinked with each other.

The organometallic fine particles may be produced by causing a metal alkoxide compound and/or a multimer thereof (partially hydrolytic condensate) to undergo a sol-gel reaction (that is, hydrolysis/polycondensation).

The metal alkoxide compound is represented by the following general formula (I):

(R₂)jM(OR₁)k (I)

wherein R₂ represents an alkyl group or an aryl group; R₁ represents an alkyl group; M represents a metal; j represents 0, 1, 2 or 3, and k represents an integer of 1 or more provided that j+k is equal to the valence of the metal M; and when R₂s are present in accordance with j, R₂s may be different or the same, and when R₁s are present in accordance with k, R₁s may be different or the same.

The alkyl group represented by R₂ is usually a lower alkyl group having about 1 to 4 carbon atoms. Examples thereof include methyl, ethyl, propyl, isopropyl, butyl, isobutyl, and sec-butyl groups, and the like. An example of the aryl group represented by R₂ is a phenyl group. The alkyl group and the aryl group may each have a substituent.

The alkyl group represented by R₁ is usually a lower alkyl group having about 1 to 4 carbon atoms. Examples thereof include methyl, ethyl, propyl, isopropyl, butyl, isobutyl, and sec-butyl groups, and the like. The alkyl group may have a substituent.

Examples of the metal atom represented by M include Si, Ti, Zr and Ta. Other examples thereof include Sn, Ge, Al, Zn, and the like. In the present invention, it is preferred to use at least two alkoxide compounds represented by the general formula (I) containing Ms different from each other, and it is preferred that one of two Ms is Si and the other metal M, which is different from Si, is selected from the group consisting of Ti, Zr and Ta. Examples of combination of the two metals include a combination of Si and Ti, that of Si and Ta, and that of Si and Zr. Of course, three metals may be combined with each other. The incorporation of the two or more metals as constituent elements into the metal compound makes it easy to control characteristics such as the refractive index as a whole organometallic oxide; thus, the incorporation is preferred for the design of the recording material.

It is preferred to use, as the alkoxide compound (I) wherein the metal M is Si, at least a compound wherein j is 1 or 2 in the formula (I). In other words, it is preferred that a direct bond to a carbon atom in an organic group (Si—C bond) is introduced into the Si atom, in the organometallic fine particles.

Specific examples of the alkoxide compound (I) wherein the metal M is Si include tetramethoxysilane, tetraethoxysilane, and tetrapropoxysilane, in each of which j=0 and k=4; methyltrimethoxysilane, ethyltrimethoxysilane, propyltrimethoxysilane, methyltriethoxysilane, ethyltriethoxysilane, propyltriethoxysilane, γ-mercaptopropyltrimethoxysilane, γ-mercaptopropyltriethoxysilane, γ-aminopropyltrimethoxysilane, γ-aminopropyltriethoxysilane, phenyltrimethoxysilane, phenyltriethoxysilane, and phenyltripropoxysilane, in each of which j=1, and k=3; dimethyldimethoxysilane, dimethyldiethoxysilane, and diphenyldimethoxysilane, in each of which j=2, and k=2; and the like.

Of these silicon compounds, preferred are, for example, tetramethoxysilane, tetraethoxysilane, methyltrimethoxysilane, ethyltrimethoxysilane, methyltriethoxysilane, ethyltriethoxysilane, and the like.

Furthermore, diphenyldimethoxysilane is preferred. When an organometallic unit wherein two phenyl groups (Phs) are bonded directly to one Si atom (Ph-Si-Ph) is incorporated into organometallic fine particles, the flexibility of the fine particles is improved and further the compatibility thereof with the photopolymerizable compound, which will be detailed later, or an organic polymer produced by the polymerization of the photopolymerizable compound becomes good. Thus, the incorporation of the organometallic unit is preferred. Moreover, the refractive index of the organometallic fine particles also becomes high. The diphenylalkoxide compound of Si is easily available, and has good reactivity in hydrolysis and polymerization. The phenyl groups may each have a substituent.

When a monoalkoxysilane (j=3 and k=1) such as trimethylmethoxysilane is present, the polymerization reaction is stopped; thus, the monoalkoxysilane can be used to adjust the molecular weight.

The alkoxide compound (I) of a metal M other than Si is not particularly limited, and specific examples thereof include alkoxide compounds of Ti, such as tetrapropoxytitanium [Ti(O—Pr)₄], and tetra-n-butoxytitanium [Ti(O-nBu)₄]; alkoxide compounds of Ta, such as pentaethoxytantalum [Ta(OEt)₅], and tetraethoxytantalum pentanedionate [Ta(OEt)₄(C₅H₇O₂)]; and alkoxide compounds of Zr, such as tetra-t-butoxyzirconium [Zr(O-tBu)₄], and tetra-n-butoxyzirconium [Zr (O-nBu)₄]. Metal alkoxide compounds besides these examples may be used.

An oligomer of the metal alkoxide compound (I) (corresponding to a partially hydrolytic condensate of the metal alkoxide compound (I)) may be used. For example, a titaniumbutoxide oligomer (corresponding to a partially hydrolytic condensate of tetrabutoxytitanium) may be used. The metal alkoxide compound (I) and the oligomer of the metal alkoxide compound (I) may be used together.

About the blend amounts of the Si alkoxide compound and the alkoxide compound of the metal M other than Si in the used metal alkoxide compound (I), it is advisable to decide the amounts appropriately so as to gain a desired refractive index. For example, it is preferred to set the atom ratio of the number of atoms of the metal(s) M other than Si (i.e., the total number of metal atoms of Ti, Zr and Ta, and any other optional metal atom (such as Ge, Sn, Al or Zn)) to the number of atoms of Si (i.e., the metal(s) M other than Si/Si) into the range of 0.1/1.0 to 10/1.0.

The organometallic fine particles may contain a very small amount of an element other than the above-mentioned elements.

In the present invention, when Ti, Zr or Ta is contained as constituting metal of the organometallic fine particles, it is preferred that a complexing ligand is coordinated to at least one portion of the metal atoms. As a complexing ligand, the so-called chelate ligand may be used. Examples thereof include β-dicarbonyl compounds, polyhydroxylated ligands, α- or β-hydroxy acids, and ethanolamines. Examples of the β-dicarbonyl compounds include β-diketones such as acetylacetone (AcAc) and benzoylacetone, and β-ketoesters such as ethyl acetoacetate (EtAcAc). Examples of the polyhydroxylated ligands include glycols (in particular, 1,3-diol type glycols such as 1,3-propanediol or 2-ethyl-1,3-hexanediol). Examples of the α- or β-hydroxy acids include lactic acid, glyceric acid, tartaric acid, citric acid, tropic acid, and benzilic acid. Other examples of the ligand include oxalic acid.

When a mixture of the alkoxide compound of Si and the alkoxide compound of the other metal(s) (such as Ti, Zr or Ta) other than Si is subjected to a sol-gel reaction, the alkoxide compound of Si is generally small in rates of hydrolysis and polymerization reaction and the alkoxide compound of the other metal(s) other than Si is large in rates of hydrolysis and polymerization reaction. As a result, an oxide of the other metal(s) other than Si aggregates so that a homogeneous sol-gel reaction product cannot be obtained. The present inventors have made investigations to find out that in the case of modifying an alkoxide compound of the other metal (s) other than Si chemically with a complexing ligand by coordinating the complexing ligand to the other metal(s) other than Si, the hydrolysis and polymerization reaction thereof can be appropriately restrained to yield a homogeneous sol-gel reaction product from a mixture of the other metal(s) other than Si with an alkoxide compound of Si.

Further, in this case, as the metal compound fine particles, the following metal complex fine particles are further generated: metal complex fine particles which contain a metal atom and an oxygen atom, have a bond between the metal atoms through the oxygen atom (metal-oxygen-metal), and have a complexing ligand coordinated to at least one portion of said metal atoms. Furthermore, the following metal complex fine particles would also be generated: metal complex fine particles which contain no Si and contain only a metal other than Si as a constituting metal.

In the case of, for example, a Ti alkoxide compound, it is preferred to coordinate a glycol thereto, examples of the glycol including 1,3-propanediol, 1,3-butanediol, 2-methyl-1,3-propanediol, 2-ethyl-1,3-hexanediol, and 2-methyl-2,4-pentanediol.

It appears that the above-mentioned glycol (that is, 1,3-diol) coordinates easily to the Ti atom of the Ti alkoxide compound as a starting material so as to be filled into coordination positions of the Ti atom, so that the glycol prevents a different coordinating-compound from coordinating to the Ti atom in the sol-gel reaction and further the hydrolysis and polymerization reaction are restrained. The coordination of the glycol to the Ti alkoxide compound is preferably attained by mixing the Ti alkoxide compound such as tetrabutoxytitanium or tetraethoxytitanium with the glycol in a solvent such as ethanol or butanol, for example, at room temperature, and then stirring the mixture. The solvent used in this case may be the same solvent used in the sol-gel reaction. In such a way, the Ti alkoxide compound to which the glycol is coordinated is prepared. It appears that any geminal diol as the glycol cannot coordinate to Ti or is poor in the ability of coordinating to Ti.

Further, in the case of Ti alkoxide compound, it is preferred to coordinate the polyalkylene glycol as a glycol to the Ti atom. Examples of the polyalkylene glycol include diethylene glycol, triethylene glycol, tetraethylene glycol, dipropylene glycol, tripropylene glycol, and tetrapropylene glycol.

In the same manner as in the 1,3-diol, the above-mentioned polyalkylene glycol is easily coordinated to the Ti atom of the Ti alkoxide compound as a starting material to fill the coordination positions of the Ti atom, and hinders any different coordinating compound from being coordinated to the Ti atom in the sol-gel reaction. The coordination of the polyalkylene glycol to the Ti alkoxide compound is preferably attained in the same way as the coordination of the 1,3-diol thereto. Out of the above-mentioned polyalkylene glycols, dipropylene glycol is preferred since the dipropylene glycol is high in coordinating ability and is easily available.

For example, in the case of the alkoxide compound of Zr, it appears that the hydrolysis and polymerization reaction are retarded by a matter that the complexing ligand is coordinated to Zr(OR)₄ wherein R represents an alkyl group to change the alkoxide compound to an alkoxide compound such as Zr(OR)₂(AcAc)₂ so that the number of alkoxy groups which can contribute to the hydrolysis and polymerization reaction decreases; and a matter that the reactivity of the alkoxy groups is retarded by a steric factor of the complexing ligand such as acetylacetone (AcAc). The same matter would be true for the alkoxide compound of Ta, i.e., Ta(OR)₅. As described above, the preferred metal compound fine particles in the present invention are a very even gel or sol form.

The amount of the used complexing ligand is not particularly limited. It is advisable to determine appropriately the amount of the complexing ligand based on the amount of the Ti alkoxide compound, the Zr alkoxide compound, or the Ta alkoxide compound, considering the above-mentioned reaction retarding effect.

The hydrolysis and polymerization reaction of the metal alkoxide compounds can be carried out by the same operation under the same conditions as in known sol-gel methods. For example, the metal alkoxide compounds (for example, the Ti alkoxide compound to which the complexing ligand is coordinated, the Si alkoxide compound, and the optional different metal alkoxide compound(s) as the need arises) in a predetermined ratio are dissolved into an appropriate good solvent to prepare a homogeneous solution. An appropriate acid catalyst is dropwise added to the solution, and the solution is stirred in the presence of water, whereby the reaction can be conducted. The amount of the solvent is not limited, and is preferably 10 to 1,000 parts by weight with respect to 100 parts by weight of the whole of the metal alkoxide compound.

Examples of such a solvent include: water; alcohols such as methanol, ethanol, propanol, isopropanol, and butanol; ethers such as diethyl ether, dioxane, dimethoxyethane and tetrahydrofuran; and N-methylpyrrolidone, acetonitrile, N,N-dimethylformamide, N,N-dimethylacetamide, dimethylsulfoxide, acetone, benzene, and the like. The solvent may be appropriately selected from these. Alternatively, a mixture of these may be used.

Examples of the acid catalyst include: inorganic acids such as hydrochloric acid, sulfuric acid, nitric acid and phosphoric acid; organic acids such as formic acid, acetic acid, trichloroacetic acid, trifluoroacetic acid, propionic acid, methanesulfonic acid, ethanesulfonic acid, and p-toluenesulfonic acid; and the like.

The hydrolysis polymerization reaction can be generally conducted at room temperature, which depends on the reactivity of the metal alkoxide compounds. The reaction can be conducted at a temperature of about 0 to 150° C., preferably at a temperature of about room temperature to 50° C. The reaction time may be appropriately determined, correspondingly to the relationship with the reaction temperature. The time is about 0.1 to 240 hours. The reaction may be conducted in an inert atmosphere such as nitrogen gas, or may be conducted under a reduced pressure of about 0.5 to 1 atm while the alcohol produced by the polymerization reaction is removed.

Before, during or after the hydrolysis, the photopolymerizable organic compound which is described later is mixed. The photopolymerizable organic compound may be mixed with the metal alkoxide compounds as the starting materials of the sol-gel reaction after, during or before the hydrolysis. In the case of the mixing after the hydrolysis, it is preferred to add and mix the photopolymerizable organic compound in the state that the sol-gel reaction system containing the metal oxide or the metal oxide precursor is sol in order to perform the mixing uniformly. The mixing of a photopolymerization initiator or photosensitizer can also be conducted before, during or after the hydrolysis.

A polycondensation reaction of the metal oxide precursor with which the photopolymerizable compound is mixed is advanced to yield a hologram recording material solution in which the photopolymerizable compound are uniformly incorporated in the sol-form organometallic fine particle matrix. The hologram recording material solution is applied onto a substrate, and then the solvent is dried. As a result, a hologram recording material layer in a film form is yielded. In such a way, the hologram recording material layer is produced wherein the photopolymerizable compound is uniformly contained in the organometallic fine particle matrix.

When the complexing-ligand-coordinating alkoxide compound of the metal other than Si (for example, a Ti alkoxide compound to which glycol coordinates) is subjected to sol-gel reaction in this way, the reaction of the alkoxide compound of the metal other than Si can be retarded so that the resultant metal compound fine particles become uniform in particle diameter. Since the particles are produced by mild reaction, the metal compound fine particles are not three-dimensionally crosslinked with each other.

It is preferred that, when a particle size distribution of the metal compound fine particles is determined by a dynamic light scattering method, a particle diameter of the metal compound fine particles is 0.5 nm or more and 50 nm or less, the particle diameter being represented by a mode value of the particle size distribution. If the mode value in the particle size distribution is more than 50 nm, Rayleigh scattering is generated in hologram recording using a blue laser. Thus, good recording characteristics are not easily obtained. Particles about which the mode value in the particle size distribution is less than 0.5 nm are not easily produced. The metal compound fine particles are preferably particles having uniform particle diameters.

The method for obtaining the mode value in the particle size distribution of the fine particles is publicly known. Specifically, Brownian motion of the fine particles is analyzed by a dynamic light scattering method, so as to obtain a relationship between the motion and the particle sizes. For this purpose, the particles are irradiated with a laser light to analyze a fluctuation in the intensity of the scattered light. From a relationship between the damping speed of a correlation function obtained from the intensity fluctuation and the Stokes-Einstein equation, the particle size distribution is calculated. The mode value (peak top value) in the particle size distribution is then obtained.

In the present invention, it is preferred that the metal compound fine particles are contained in an amount of 70% by weight or more and 95% by weight or less with respect to the hologram recording material (nonvolatile components). A large portion of the balance is occupied by the photopolymerizable organic compound, and other optional components (such as a photopolymerization initiator and a photosensitizer) are contained in the balance. If the amount of the metal compound fine particles is less than 70% by weight, the amount of the photopolymerizable organic compound becomes large so that the hologram recording layer easily undergoes recording shrinkage. On the other hand, if the amount of the metal compound fine particles is more than 95% by weight, a change in the refractive index is not easily caused by recording.

In the present invention, the photopolymerizable compound is a photopolymerizable monomer. As the photopolymerizable compound, a compound selected from a radical polymerizable compound and a cation polymerizable compound can be used.

The radical polymerizable compound is not particularly limited as long as the compound has in the molecule one or more radical polymerizable unsaturated double bonds. For example, a monofunctional and multifunctional compound having a (meth) acryloyl group or a vinyl group can be used. The wording “(meth)acryloyl group” is a wording for expressing a methacryloyl group and an acryloyl group collectively.

Examples of the compound having a (meth)acryloyl group, out of such radical polymerizable compounds, include monofunctional (meth)acrylates such as phenoxyethyl (meth)acrylate, 2-methoxyethyl (meth)acrylate, 2-hydroxyethyl (meth)acrylate, benzyl (meth)acrylate, cyclohexyl (meth)acrylate, ethoxydiethylene glycol (meth)acrylate, methoxypolyethylene glycol (meth)acrylate, methyl (meth)acrylate, polyethylene glycol (meth)acrylate, polypropylene glycol (meth)acrylate, and stearyl (meth)acrylate; and

polyfunctional (meth)acrylates such as trimethylolpropane tri(meth)acrylate, pentaerythritol tetra(meth)acrylate, dipentaerythritol hexa(meth)acrylate, diethylene glycol di(meth)acrylate, triethylene glycol di(meth)acrylate, tetraethylene glycol di(meth)acrylate, polyethylene glycol di(meth)acrylate, bis(2-hydroxyethyl)isocyanurate di(meth)acrylate, and 2,2-bis[4-(acryloxy-diethoxy)phenyl]propane. However, the compound having a (meth)acryloyl group is not necessarily limited thereto.

Examples of the compound having a vinyl group include monofunctional vinyl compounds such as monovinylbenzene, and ethylene glycol monovinyl ether; and polyfunctional vinyl compounds such as divinylbenzene, ethylene glycol divinyl ether, diethylene glycol divinyl ether, and triethylene glycol divinyl ether. However, the compound having a vinyl group is not necessarily limited thereto.

One kind of the radical polymerizable compound may be used, and two or more kinds thereof are used together. In the case of making the refractive index of the fine particles high and making the refractive index of the organic polymer low, in the present invention, a compound having no aromatic group to have low refractive index (for example, refractive index of 1.5 or less) is preferred out of the above-mentioned radical polymerizable compounds. In order to make the compatibility with the fine particles better, preferred is a more hydrophilic glycol derivative such as polyethylene glycol (meth)acrylate and polyethylene glycol di(meth)acrylate.

The cation polymerizable compound is not particularly limited about the structure as long as the compound has at least one reactive group selected from a cyclic ether group and a vinyl ether group.

Examples of the compound having a cyclic ether group out of such cation polymerizable compounds include compounds having an epoxy group, an alicyclic epoxy group or an oxetanyl group.

Specific examples of the compound having an epoxy group include monofunctional epoxy compounds such as 1,2-epoxyhexadecane, and 2-ethylhexyldiglycol glycidyl ether; and polyfunctional epoxy compounds such as bisphenol A diglycidyl ether, novolak type epoxy resins, trisphenolmethane triglycidyl ether, 1,4-butanediol diglycidyl ether, 1,6-hexanediol diglycidyl ether, glycerin triglycidyl ether, trimethylolpropane triglycidyl ether, propylene glycol diglycidyl ether, and polyethylene glycol diglycidyl ether.

Specific examples of the compound having an alicyclic epoxy group include monofunctional compounds such as 1,2-epoxy-4-vinylcyclohexane, D-2,2,6-trimethyl-2,3-epoxybicyclo[3,1,1]heptane, and 3,4-epoxycyclohexylmethyl (meth)acrylate; and polyfunctional compounds such as 2,4-epoxycyclohexylmethyl-3,4-epoxycyclohexane carboxylate, bis(3,4-epoxycyclohexylmethyl) adipate, 2-(3,4-epoxycyclohexyl-5,5-spiro-3,4-epoxy)cyclohexanone-m-dioxane, bis(2,3-epoxycyclopentyl)ether, and EHPE-3150 (alicyclic epoxy resin, manufactured by Dicel Chemical Industries, Ltd.).

Specific examples of the compound having an oxetanyl group include monofunctional oxetanyl compounds such as 3-ethyl-3-hydroxymethyloxetane, 3-ethyl-3-(2-ethylhexyloxymethyl)oxetane, and 3-ethyl-3-(cyclohexyloxymethyl)oxetane; and polyfunctional oxetanyl compounds such as 1,4-bis[(3-ethyl-3-oxetanylmethoxy)methyl]benzene, 1,3-bis[(3-ethyl-3-oxetanylmethoxy)methyl]propane, ethylene glycol bis(3-ethyl-3-oxetanylmethyl)ether, trimethylolpropanetris(3-ethyl-3-oxetanylmethyl)ether, pentaerythritol tetrakis(3-ethyl-3-oxetanylmethyl)ether, dipentaerythritol hexakis(3-ethyl-3-oxetanylmethyl)ether, and ethylene oxide modified bisphenol A bis(3-ethyl-3-oxetanylmethyl)ether.

Specific examples of the compound having a vinyl ether group, out of the cation polymerizable compounds, include monofunctional compounds such as triethylene glycol monovinyl ether, cyclohexanedimethanol monovinyl ether, and 4-hydroxycyclohexyl vinyl ether; and polyfunctional compounds such as triethylene glycol divinyl ether, tetraethylene glycol divinyl ether, trimethylolpropane trivinyl ether, cyclohexane-1,4-dimethylol divinyl ether, 1,4-butanediol divinyl ether, polyester divinyl ether, and polyurethane polyvinyl ether.

One kind of the cation polymerizable compound may be used, or two or more kinds thereof may be used together. As the photopolymerizable compound, an oligomer of the cation polymerizable compounds exemplified above may be used. In the case of making the refractive index of the fine particles high and making the refractive index of the organic polymer low, in the present invention, a compound having no aromatic group to have low refractive index (for example, refractive index of 1.5 or less) is preferred out of the above-mentioned cation polymerizable compounds. In order to make the compatibility with the fine particles better, preferred is a more hydrophilic glycol derivative such as polyethylene glycol diglycidyl ether.

In the present invention, it is advisable to use the photopolymerizable compound in an amount of, for example, about 5 to 30% by weight, preferably 10 to 20% by weight, with respect to the hologram recording material (nonvolatile components). If the amount is less than 5% by weight, a large change in the refractive index is not easily obtained in recording. If the amount is more than 30% by weight, the hologram recording layer shrinks in recording.

In the present invention, it is preferred that the hologram recording material further contains a photopolymerization initiator corresponding to the wavelength of recording light. When the photopolymerization initiator is contained in the hologram recording material, the polymerization of the photopolymerizable compound is promoted by the light exposure at the time of recording. Consequently, a higher sensitivity is achieved.

When a radical polymerizable compound is used as the photopolymerizable compound, a radical photoinitiator is used. On the other hand, when a cation polymerizable compound is used as the photopolymerizable compound, a cation photoinitiator is used.

Examples of the radical photoinitiator include Darocure 1173, Irgacure 784, Irgacure 651, Irgacure 184 and Irgacure 907 (each manufactured by Ciba Specialty Chemicals Inc.). The content of the radical photoinitiator is, for example, about 0.1 to 10% by weight, preferably about 0.5 to 5% by weight on the basis of the radical polymerizable compound.

As the cation photoinitiator, for example, an onium salt such as a diazonium salt, a sulfonium salt, or a iodonium salt can be used. It is particularly preferred to use an aromatic onium salt. Besides, an iron-arene complex such as a ferrocene derivative, an arylsilanol-aluminum complex, or the like can be preferably used. It is advisable to select an appropriate initiator from these. Specific examples of the cation photoinitiator include Cyracure UVI-6970, Cyracure UVI-6974 and Cyracure UVI-6990 (each manufactured by Dow Chemical Co. in USA), Irgacure 264 and Irgacure 250 (each manufactured by Ciba Specialty Chemicals Inc.), and CIT-1682 (manufactured by Nippon Soda Co., Ltd.). The content of the cation photoinitiator is, for example, about 0.1 to 10% by weight, preferably about 0.5 to 5% by weight on the basis of the cation polymerizable compound.

The hologram recording material may preferably contain a dye that functions as a photosensitizer corresponding to the wavelength of recording light or the like besides the photopolymerization initiator. Examples of the photosensitizer include thioxanthones such as thioxanthen-9-one, and 2,4-diethyl-9H-thioxanthen-9-one; xanthenes; cyanines; melocyanines; thiazines; acridines; anthraquinones; and squaliriums. It is advisable to set an amount to be used of the photosensitizer into the range of about 3 to 50% by weight of the radical photoinitiator, for example, about 10% by weight thereof.

In such a way, the hologram recording material wherein the photopolymerizable organic compound is uniformly contained in the organometallic fine particle matrix is produced, and the hologram recording layer comprising said hologram recording material is produced.

The above-described organometallic fine particles are in the form of a very homogenous gel or sol so as to function as a matrix, or a dispersing medium for the photopolymerizable compound in the hologram recording material layer. In other words, the photopolymerizable compound, which is in a liquid phase, is evenly and compatibly dispersed in the sol- or gel-form organometallic fine particles.

When the light having coherency is irradiated onto the hologram recording material layer, the photopolymerizable organic compound (monomer) undergoes polymerization reaction in the exposed portion so as to be polymerized, and further the photopolymerizable organic compound diffuses and migrates from the unexposed portion into the exposed portion so that the polymerization of the exposed portion further advances. As a result, an area where the polymer produced from the photopolymerizable organic compound is large in amount and an area where the polymer is small in amount are formed in accordance with the intensity distribution of the light. At this time, the organometallic fine particles migrate from the area where the polymer is large in amount to the area where the polymer is small in amount, so that the area where the polymer is large in amount becomes an area where the organometallic fine particles are small in amount and the area where the polymer is small in amount becomes an area where the organometallic fine particles are large in amount. In this way, the light exposure causes the formation of the area where the polymer is large in amount and the area where the organometallic fine particles are large in amount. When a refractive index difference exists between the polymer and the organometallic fine particles, a refractive index change is recorded in accordance with the light intensity distribution.

The hologram recording medium of the present invention comprises at least the above-mentioned hologram recording material layer. Usually, the hologram recording medium comprises a supporting substrate (that is, a substrate), and a hologram recording material layer; however, the medium may be made only of a hologram recording material layer without having any supporting substrate. For example, a medium composed only of a hologram recording material layer may be obtained by forming the hologram recording material layer onto the substrate by application, and then peeling the hologram recording material layer off from the substrate. In this case, the hologram recording material layer is, for example, a layer having a thickness in the order from submillimeters to millimeters.

The hologram recording medium of the present invention is suitable for record and reproduction using not only a green laser light but also a blue laser light having a wavelength of 350 to 450 nm. When the reproduction is made using transmitted light, the medium preferably has a light transmittance of 50% or more at a wavelength of 405 nm. When the reproduction is made using reflected light, the medium preferably has a light reflectance of 25% or more at a wavelength of 405 nm.

The hologram recording medium is either of a medium having a structure for performing reproduction using transmitted light (hereinafter referred to as a transmitted light reproducing type medium), and a medium having a structure for performing reproduction using reflected light (hereinafter referred to as a reflected light reproducing type medium) in accordance with an optical system used for the medium.

The transmitted light reproducing type medium is constructed in such a manner that a laser light for readout is irradiated into the medium, the laser light irradiated therein is diffracted by signals recorded in its hologram recording material layer, and the laser light transmitted through the medium is converted to electric signals by means of an image sensor. In other words, in the transmitted light reproducing type medium, the laser light to be detected is transmitted through the medium toward the medium side opposite to the medium side into which the reproducing laser light is irradiated. The transmitted light reproducing type medium usually has a structure wherein its recording material layer is sandwiched between two supporting substrates. In an optical system used for the medium, the image sensor, for detecting the transmitted laser light, is set up in the medium side opposite to the medium side into which the reproducing laser light emitted from a light source is irradiated.

Accordingly, in the transmitted light reproducing type medium, the supporting substrate, the recording material layer, and any other optional layer(s) are each made of a light-transmitting material. It is unallowable that any element blocking the transmission of the reproducing laser light is substantially present. The supporting substrate is usually a rigid substrate made of glass or resin.

In the meantime, the reflected light reproducing type medium is constructed in such a manner that a laser light for readout is irradiated into the medium, the laser light irradiated therein is diffracted by signals recorded in its hologram recording material layer, and then, the laser light is reflected on its reflective film, and the reflected laser light is converted to electric signals by means of an image sensor. In other words, in the reflected light reproducing type medium, the laser light to be detected is reflected toward the same medium side as the medium side into which the reproducing laser light is irradiated. The reflected light reproducing type medium usually has a structure wherein the recording material layer is formed on a supporting substrate positioned at the medium side into which the reproducing laser light is irradiated; and a reflective film and an another supporting substrate are formed on the recording material layer. In an optical system used for the medium, the image sensor, for detecting the reflected laser light, is set up in the same medium side as the medium side into which the reproducing laser light emitted from a light source is irradiated.

Accordingly, in the reflected light reproducing type medium, the supporting substrate positioned at the medium surface side into which the reproducing laser light is irradiated, the recording material layer, and other optional layer(s) positioned nearer to the medium side into which the reproducing laser light is irradiated than the reflective film are each made of a light-transmitting material. It is unallowable that these members each substantially contain an element blocking the incident or reflective reproducing laser light. The supporting substrate is usually a rigid substrate made of glass or resin. The supporting substrate positioned at the medium surface side into which the reproducing laser light is irradiated is required to have a light-transmitting property.

In any case of the transmitted light reproducing type medium and the reflected light reproducing type medium, it is important that the hologram recording material layer has a high light transmittance of, for example, 50% or more at a wavelength of 405 nm. For example, in the case of considering a layer (100 μm in thickness) composed only of the matrix material (fine particle material), it is preferred that the layer has a high light transmittance of 90% or more at a wavelength of 405 nm.

The hologram recording material layer obtained as above-mentioned has a high transmittance to a blue laser. Therefore, even if a thickness of the recording material layer is set to 100 μm, a recording medium having a light transmittance of 50% or more, preferably 55% or more at a wavelength of 405 nm is obtained when the medium is a transmitted light reproducing type medium; or a recording medium having a light reflectance of 25% or more, preferably 27.5% or more at a wavelength of 405 nm is obtained when the medium is a reflected light reproducing type medium. In order to attain holographic memory recording characteristics such that a high multiplicity is ensured, necessary is a recording material layer having a thickness of 100 μm or more, preferably 200 μm or more. According to the present invention, however, even if the thickness of the recording material layer is set to, for example, 1 mm, it is possible to ensure a light transmittance of 50% or more at a wavelength of 405 nm (when the medium is a transmitted light reproducing type medium), or a light reflectance of 25% or more at a wavelength of 405 nm (when the medium is a reflected light reproducing type medium).

When the above described hologram recording material layer is used, a hologram recording medium having a recording layer thickness of 100 μm or more, which is suitable for data storage, can be obtained. The hologram recording medium can be produced by forming the hologram recording material in a film form onto a substrate, or sandwiching the hologram recording material in a film form between substrates.

In a transmitted light reproducing type medium, it is preferred to use, for the substrate(s), a material transparent to a recording/reproducing wavelength, such as glass or resin. It is preferred to form an anti-reflection film against the recording/reproducing wavelength for preventing noises, or give address signals and so on, onto the substrate surface at the side opposite to the layer of the hologram recording material. In order to prevent interface reflection, which results in noises, it is preferred that the refractive index of the hologram recording material and that of the substrate are substantially equal to each other. It is allowable to form, between the hologram recording material layer and the substrate, a refractive index adjusting layer comprising a resin material or oil material having a refractive index substantially equal to that of the recording material or the substrate. In order to keep the thickness of the hologram recording material layer between the substrates, a spacer suitable for the thickness between the substrates may be arranged. End faces of the recording material medium are preferably subjected to treatment for sealing the recording material.

About the reflected light reproducing type medium, it is preferred that the substrate positioned at the medium surface side into which a reproducing laser light is irradiated is made of a material transparent to a recording and reproducing wavelength, such as glass or resin. As the substrate positioned at the medium surface side opposite to the medium surface side into which a reproducing laser light is irradiated, a substrate having thereon a reflective film is used. Specifically, a reflective film made of, for example, Al, Ag, Au or an alloy made mainly of these metals and the like is formed on a surface of a rigid substrate (which is not required to have a light-transmitting property), such as glass or resin, by vapor deposition, sputtering, ion plating, or any other film-forming method, whereby a substrate having thereon the reflective film is obtained. A hologram recording material layer is provided so as to have a predetermined thickness on the surface of the reflective film of this substrate, and further a light-transmitting substrate is caused to adhere onto the surface of this recording material layer. An adhesive layer, a flattening layer and the like may be provided between the hologram recording material layer and the reflective film, and/or between the hologram recording material layer and the light-transmitting substrate. It is also unallowable that these optional layers hinder the transmission of the laser light. Others than this matter are the same as in the above-mentioned transmitted light reproducing type medium.

The hologram recording medium having the hologram recording layer comprising the hologram recording material in the present invention can be preferably used not only in a system wherein record and reproduction are made using a green laser light but also in a system wherein record and reproduction are made using a blue laser light having a wavelength of 350 to 450 nm.

### EXAMPLES

The present invention will be specifically described by way of the following examples; however, the present invention is not limited to the examples.

### Example 1

### Synthesis of a Metal Compound Fine Particle Material

At room temperature, 3.65 g of tetra-n-butoxytitanium (Ti(OBu)₄, manufactured by Kojundo Chemical Lab. Co., Ltd.) was mixed with 3.1 g of 2-ethyl-1,3-hexanediol (manufactured by Tokyo Chemical Industry Co., Ltd.) in 1 mL of a n-butanol solvent. The mixture was stirred for 10 minutes. The mole ratio of Ti(OBu)₄/2-ethyl-1,3-hexanediol was 1/2. To this reaction solution was added 2.6 g of diphenyldimethoxysilane (trade name: LS-5300, manufactured by Shin-Etsu Chemical Co., Ltd.) to prepare a metal alkoxide solution. The mole ratio of Ti/Si was 1/1.

To the metal alkoxide solution was dropwise added a solution composed of 0.2 mL of water, 0.08 mL of a 2-N solution of hydrochloric acid in water, and 1 mL of an ethanol solvent at room temperature while the alkoxide solution was stirred. The solution was continuously stirred for 1 hour to conduct a hydrolysis and condensation reaction. In this way, a sol solution was yielded. It appears that various particles are present in this sol solution.

About the resultant sol solution, a diameter of the particles was measured by a dynamic light scattering method. As a result, the mode value in the particle size distribution was about 1 nm. The measurement was made with a device (trade name: ZETASIZER Nano-ZS) manufactured by Sysmex.

### (Photopolymerizable Compound)

To 100 parts by weight of polyethylene glycol diacrylate (ARONIX M-245, manufactured by Toagosei Co., Ltd.) as a photopolymerizable compound were added 3 parts by weight of a photopolymerization initiator IRGACURE-907 (IRG-907, manufactured by Ciba Specialty Chemicals K.K.) and 0.3 part by weight of thioxanthen-9-one as a photosensitizer, so as to prepare a mixture containing the photopolymerizable compound.

### Hologram Recording Material

The sol solution and the mixture containing the photopolymerizable compound were mixed with each other at a room temperature to set the ratio of the metal compound fine particle material (as a nonvolatile component) and that of the photopolymerizable compound to 90 parts by weight and 10 parts by weight, respectively. Furthermore, the sol-gel reaction was sufficiently advanced for 1 hour in a state that light was shielded from the system, so as to yield a hologram recording material solution.

The resultant hologram recording material solution was applied onto a glass substrate, dried, and then subjected to an annealing treatment to prepare a recording medium sample, as will be detailed below.

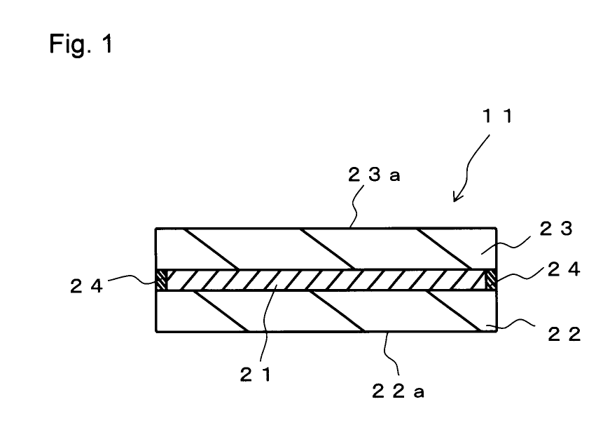

With reference to FIG. 1, which schematically illustrates a cross section of a hologram recording medium, explanation will be described.

A glass substrate (22) having a thickness of 1 mm and having one surface on which an anti-reflection film (22a) was formed was prepared. A spacer (24) having a predetermined thickness was put on a surface of the glass substrate (22) on which the anti-reflection film (22a) was not formed, and the hologram recording material solution obtained was applied onto said surface of the glass substrate (22). The resultant was dried at a room temperature for 1 hour, then dried at 40° C. for 24 hours to volatilize the solvent. Further, the resultant was heated for 48 hours under the reduced pressure of 100 hPa and 80° C. Through this annealing treatment step, the gelation (condensation reaction) of the organometallic compound was further advanced so as to yield a hologram recording material layer (21) having a dry film thickness of 450 μm wherein the organometallic compound and the photopolymerizable compound were uniformly dispersed.

### Hologram Recording Medium

The hologram recording material layer (21) formed on the glass substrate (22) was covered with another glass substrate (23), 1 mm in thickness, on one surface of which an anti-reflection film (23a) was formed. At this time, the covering was performed in the state that the surface of the glass substrate (23) on which the anti-reflection film (23a) was not formed was brought into contact with the surface of the hologram recording material layer (21). Moreover, at this time, the covering was slowly and carefully performed to cause air bubbles not to be contained in the vicinity of the interface between the glass substrate (23) and the recording material layer (21). This manner gave a hologram recording medium (11) having a structure wherein the hologram recording material layer (21) was sandwiched between the two glass substrates (22) and (23).

### Evaluation of Characteristics

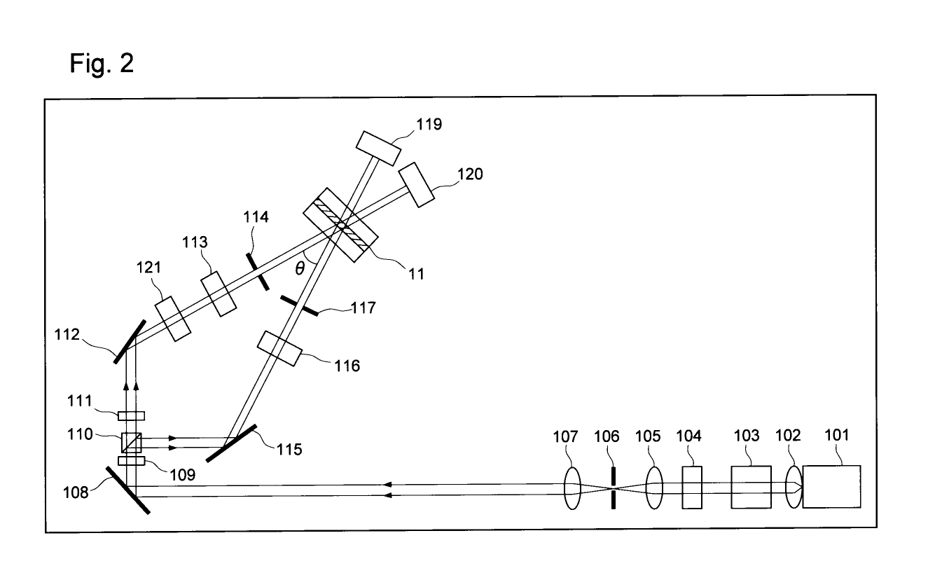

About the resultant hologram recording medium sample, characteristics thereof were evaluated in a hologram recording optical system as illustrated in FIG. 2. The direction along which the paper surface on which FIG. 2 is drawn stretches is defined as a horizontal direction for convenience' sake.

In FIG. 2, the hologram recording medium sample (11) was set to make the recording material layer perpendicular to the horizontal direction.

In the hologram recording optical system illustrated in FIG. 2, a light source (101) for emitting a semiconductor laser (wavelength: 405 nm) in a single mode oscillation was used. Light emitted from this light source (101) was subjected to a spatial filtrating treatment by means of a beam shape adjuster (102), a light isolator (103), a shutter (104), a convex lens (105), a pinhole (106), and a convex lens (107), so as to be collimated, thereby enlarging the light into a beam diameter of about 10 mm. The enlarged beam was passed through a mirror (108) and a ½ wavelength plate (109) to take out 45° (45 degree) polarized light. The light was split into an S wave and a P wave (the ratio of S wave/P wave is 1/1) through a polarized beam splitter (110). The S wave obtained by the splitting was passed through a mirror (115), a polarizing filter (116), and an iris diaphragm (117) while a ½ wavelength plate (111) was used to convert the P wave obtained by the splitting to an S wave and then the S wave was passed through a mirror (112), a polarizing filter (113) and an iris diaphragm (114). In this way, the total incident angle θ of the two light fluxes irradiated into the hologram recording medium sample (11) was set to 43°, so as to record interference fringes of the two light fluxes in the sample (11).

The sample (11) was rotated in the horizontal direction to attain multiplexing (angle multiplexing; sample angle: −21° to +21°, angle interval: 0.6°), thereby attaining hologram recording. The multiplicity was 71. At the time of recording, the sample was exposed to the light while the iris diaphragms (114) and (117) were each set to a diameter of 4 mm. At a position where the angle of the surfaces of the sample (11) to the bisector (not illustrated) of the angle θ made by the two light fluxes was 90°, the above-mentioned sample angle was set to ±0°.

After the hologram recording, in order to react remaining unreacted components, a sufficient quantity of blue light having a wavelength of 400 nm was irradiated to the whole of the surface of the sample (11) from a blue LED. At this time, the light was irradiated through an acrylic resin diffuser plate having a light transmittance of 80% so as to cause the irradiated light not to have coherency (the light irradiation is called post-cure). At the time of reproduction, with shading by the shutter (121), the iris diaphragm (117) was set into a diameter of 1 mm and only one light flux was irradiated. The sample (11) was continuously rotated into the horizontal direction from −23° to +23°. In the individual angle positions, the diffraction efficiency was measured with a power meter (120). When a change in the volume (a recording shrinkage) or a change in the average refractive index of the recording material layer is not generated before and after the recording, the diffraction peak angle in the horizontal direction at the time of the recording is consistent with that at the time of the reproduction. Actually, however, a recording shrinkage or a change in the average refractive index is generated; therefore, the diffraction peak angle in the horizontal direction at the time of the reproduction is slightly different from the diffraction peak angle in the horizontal direction at the time of the recording. For this reason, at the time of the reproduction, the angle in the horizontal direction was continuously changed and then the diffraction efficiency was calculated from the peak intensity when a diffraction peak made its appearance. In FIG. 2, reference number (119) represents a power meter not used in this example.

At this time, a dynamic range M/# (the sum of the square roots of the diffraction efficiencies in individual diffraction peaks) was a high value of 26.5, which was a converted value obtained in a case where the thickness of the hologram recording material layer was regarded as 1 mm. An average recording sensitivity from the start of light exposure to the time when the M/# reached 80% of the above-mentioned dynamic range value M/# was 0.9 cm/mJ.

Before the recording exposure (i.e., at the initial stage), the light transmittance of the medium (recording layer thickness: 450 μm) was 82.5% at 405 nm. After the recording (i.e., after post curing with a blue LED), the light transmittance of the medium was 79.0% at 405 nm. Thus, the initial light transmittance was substantially kept. Herein, the light transmittance T after the recording is defined as follows:

Namely, in a case where the incident light intensity when the medium undergoes reproducing is represented by li, the intensity of the transmitted light (zero-order light) at the angle θ of the light is represented by lt(θ), and the intensity of the first-order diffracted light is represented by ld(θ), a value T obtained by averaging the transmittances T(θ)'s each represented by the following equation over the range of angles from −23° to +23° is defined as the light transmittance after the recording.

T(θ)=[lt(θ)+ld(θ)]/li

T=∫T(θ)/Δθ

### Comparative Example 1

### Synthesis of a Metal Compound Fine Particle Material

At room temperature, 3.65 g of tetra-n-butoxytitanium (Ti(OBu)₄, manufactured by Kojundo Chemical Lab. Co., Ltd.) was mixed in 10 mL of a n-butanol solvent. The mixture was stirred for 10 minutes. To this solution was added 2.6 g of diphenyldimethoxysilane (trade name: LS-5300, manufactured by Shin-Etsu Chemical Co., Ltd.) to prepare a metal alkoxide solution. The mole ratio of Ti/Si was 1/1.

To the metal alkoxide solution was dropwise added a solution composed of 0.2 mL of water, 0.08 mL of a 2-N solution of hydrochloric acid in water, and 1 mL of an ethanol solvent at room temperature while the alkoxide solution was stirred. As a result, the metal alkoxide solution gelatinized.

An n-butanol solvent was added to this gel. However, the gel was not dissolved. It appears that the gel was a three-dimensionally crosslinked gel. This gel was a semitransparent gel. Such a gel cannot be used as a hologram recording material.

What is claimed is:

1. A hologram recording material comprising at least metal compound fine particles and a photopolymerizable compound,
wherein the metal compound fine particles comprise organometallic fine particles which contain a metal atom, an organic group, and an oxygen atom, have a direct bond between the metal atom and a carbon atom in the organic group (a metal-carbon bond), and have a bond between the metal atoms through the oxygen atom (a metal-oxygen-metal bond); and
the metal compound fine particles are not crosslinked with each other.

2. The hologram recording material according to claim 1, wherein a particle diameter of the metal compound fine particles is 0.5 nm or more and 50 nm or less, the particle diameter being represented by a mode value of a particle size distribution of said fine particles as determined by a dynamic light scattering method.

3. The hologram recording material according to claim 1, wherein the organometallic fine particles contain at least two kinds of metals as the metal atom, one of the at least two kinds of metals is Si, and the metal(s) other than Si is/are selected from the group consisting of Ti, Zr and Ta.

4. The hologram recording material according to claim 3, wherein a complexing ligand is coordinated to at least one portion of said metal atom other than Si in the organometallic fine particles.

5. The hologram recording material according to claim 1, wherein the metal compound fine particles further comprise metal complex fine particles which contain a metal atom and an oxygen atom, have a bond between the metal atoms through the oxygen atom (a metal-oxygen-metal bond), and have a complexing ligand coordinated to at least one portion of said metal atom; and
the metal compound fine particles are not crosslinked with each other.

6. The hologram recording material according to claim 1, wherein the metal compound fine particles are contained in an amount of 70% by weight or more and 95% by weight or less with respect to the hologram recording material as a nonvolatile component.

7. The hologram recording material according to claim 1, which further comprises a photopolymerization initiator.

8. A hologram recording medium having a hologram recording layer comprising the hologram recording material according to claim 1.

9. A holographic memory system, using a hologram recording medium having a hologram recording layer comprising the hologram recording material according to claim 1.

10. A hologram recording material comprising at least metal compound fine particles and a photopolymerizable compound,
wherein the metal compound fine particles comprise metal complex fine particles which contain a metal atom and an oxygen atom, have a bond between the metal atoms through the oxygen atom (a metal-oxygen-metal bond), and have a complexing ligand coordinated to at least one portion of said metal atom; and
the metal compound fine particles are not crosslinked with each other.

11. The hologram recording material according to claim 10, wherein a particle diameter of the metal compound fine particles is 0.5 nm or more and 50 nm or less, the particle diameter being represented by a mode value of a particle size distribution of said fine particles as determined by a dynamic light scattering method.

12. The hologram recording material according to claim 10, wherein the metal compound fine particles are contained in an amount of 70% by weight or more and 95% by weight or less with respect to the hologram recording material as a nonvolatile component.

13. The hologram recording material according to claim 10, which further comprises a photopolymerization initiator.

14. A hologram recording medium having a hologram recording layer comprising the hologram recording material according to claim 10.

15. A holographic memory system, using a hologram recording medium having a hologram recording layer comprising the hologram recording material according to claim 10.
